(19) United States
(12) Patent Application Publication
(10) Pub. No.: US 2014/0346391 A1
(43) Pub. Date: Nov. 27, 2014

(54) POLYSILOXANE HYDROXIDE THIN-FILM RINSE SOLUTION, AND POLYSILOOXAZINE HYDROXIDE THIN-FILM PATTERN-FORMING METHOD USING THE SAME

(71) Applicant: CHEIL INDUSTRIES INC., Gumi-si Gyeongsangbuk-do (KR)

(72) Inventors: Bong-Hwan Kim, Uiwang-si (KR); Taek-Soo Kwak, Uiwang-si (KR); Jin-Hee Bae, Uiwang-si (KR); Hui-Chan Yun, Uiwang-si (KR); Sang-Hak Lim, Uiwang-si (KR); Sang-Kyun Kim, Uiwang-si (KR); Jin-Wook Lee, Uiwang-si (KR)

(21) Appl. No.: 14/357,689

(22) PCT Filed: Oct. 31, 2012
(86) PCT No.: PCT/KR2012/009044

§ 371 Date: May 12, 2014

(30) Foreign Application Priority Data
Nov. 10, 2011 (KR) 10-2011-0117090

(51) Int. Cl. C09K 13/00; H01L 21/02

(52) U.S. Cl. CPC C09K 13/00; H01L 21/0206
USPC 252/79.1

(57) ABSTRACT

Provided is a rinse solution for a hydrogenated polysiloxazane thin film including an additive selected from an alcohol-based solvent, an ester-based solvent, a silanol-based solvent, an alkoxysilane-based solvent, an alkylsilazane-based solvent, and a combination thereof in an amount of 0.01 wt % to 7 wt % based on the total amount of the rinse solution.

### TECHNICAL FIELD

This disclosure relates to a rinse solution for a hydrogenated polysiloxazane thin film, and a method of patterning a hydrogenated polysiloxazane thin film using the same.

### BACKGROUND ART

Hydrogenated polysiloxazane is converted into a compact film when coated on a substrate having protrusions and depressions and heated, and thus fills a gap among protrusions and depressions and planarizes the protrusions and depressions, and accordingly, researches on its use as an insulation layer, a separation membrane, a hard coating, and the like are being undertaken. This silica film is widely used as, for example, an interlayer insulating layer, a planarization layer, a passivation film, a device insulation interlayer, and the like for a semiconductor device such as an LSI, a TFT liquid crystal display (LCD), and the like.

The silica film is formed in the semiconductor device and the like by generally adopting the following method. That is, a hydrogenated polysiloxazane solution is spin-coated on a substrate having a semiconductor, a wire, an electrode, and the like formed thereon as necessary, and thus having a step difference or no step difference, heated to remove a solvent therein, and subsequently baked at greater than or equal to 350° C. so that the hydrogenated polysiloxazane solution may be converted into a silica film, and the silica film is used as an insulation interlayer, a planarization layer, a passivation film, an insulation interlayer between devices, and the like.

However, when the hydrogenated polysiloxazane solution is spin-coated on the substrate in this method, a bead is formed around the substrate, and simultaneously the hydrogenated polysiloxazane solution flows around to the rear side of the substrate. In order to prevent the film from having a non-uniform thickness due to the bead around the substrate, an edge bead removal treatment (hereinafter, EBR) is performed by coating or spraying a treatment solvent around the film formed on the surface of the substrate after coating the hydrogenated polysiloxazane solution, and in addition, the rear side of the substrate is rinsed to remove and clean the hydrogenated polysiloxazane going around the surface and attached thereto.

The hydrogenated polysiloxazane film formed in the above method may need to be stripped off from the substrate depending on a post-treatment, or the hydrogenated polysiloxazane attached to a coating device such as a spin-coater and the like may need to be cleaned and removed.

This polysiloxazane is not sufficiently rinsed or removed by a conventional rinse solution or stripper, and thus may form a film thickness difference called a hump at a boundary between a part where the film is removed and another part where the film is not removed in the edge cut region of the substrate when the EBR treatment is performed. The hump may cause a crack or stripping of the film during baking, and accordingly, a solvent for the EBR treatment that can obtain a film having a much better shape on the edge cut region after the EBR treatment is required.

### DISCLOSURE

### Technical Problem

One embodiment of the present invention provides a rinse solution for a hydrogenated polysiloxazane thin film capable of precisely stripping off a hydrogenated polysiloxazane thin film on the edge of a substrate.

Another embodiment of the present invention provides a method of patterning a hydrogenated polysiloxazane thin film using the rinse solution for a hydrogenated polysiloxazane thin film.

Still another embodiment of the present invention provides an insulation layer formed by using the rinse solution for a hydrogenated polysiloxazane thin film.

### Technical Solution

According to one embodiment of the present invention, a rinse solution for a hydrogenated polysiloxazane thin film includes an additive selected from an alcohol-based solvent, an ester-based solvent, a silanol-based solvent, an alkoxysilane-based solvent, an alkylsilazane-based solvent, and a combination thereof in an amount of 0.01 wt % to 7 wt % based on the total weight of the rinse solution.

The additive may be included in an amount of 0.02 wt % to 5 wt % based on the total weight of the rinse solution for a hydrogenated polysiloxazane thin film.

The additive may be selected from n-butanol, octanol, trimethylsilanol, triethylsilanol, hexamethyldisilazane, hexaethyldisilazane, tetraethoxysilane, tetramethoxysilane, and a combination thereof.

The rinse solution may further include a solvent selected from an aromatic hydrocarbon-based solvent, an ether-based solvent, a terpine-based solvent, and a combination thereof in an amount of 93 wt % to 99.9 wt % based on the total weight of the rinse solution.

The aromatic hydrocarbon-based solvent may be selected from xylene, ethylbenzene, propylbenzene, butylbenzene, mesitylene, and a combination thereof.

The ether-based solvent may be selected from di-n-butylether, anisole, and a combination thereof.

The terpine-based solvent may be selected from p-methane, p-pentane, p-cymene, pinene, turpentine, and a combination thereof.

According to another embodiment of the present invention, a method of patterning a hydrogenated polysiloxazane thin film by using the rinse solution for a hydrogenated polysiloxazane thin film is provided.

According to still another embodiment of the present invention, an insulation layer formed by using the rinse solution for a hydrogenated polysiloxazane thin film is provided.

Other embodiments of the present invention are described in the detailed description.

### Advantageous Effects

A rinse solution for a hydrogenated polysiloxazane thin film capable of precisely stripping off a hydrogenated polysiloxazane thin film on the edge of a substrate is provided.

### DESCRIPTION OF THE DRAWINGS

FIG. 1 shows a method of evaluating stripping characteristics of a rinse solution for a hydrogenated polysiloxazane thin film.

### MODE FOR INVENTION

Hereinafter, embodiments of the present invention are described in detail. However, these embodiments are exemplary, and this disclosure is not limited thereto.

In the present specification, when a definition is not otherwise provided, “substituted” refers to one substituted with at least one substituent selected from a halogen atom (F, Cl, Br, or I), a hydroxy group, a nitro group, a cyano group, an imino group (=NH, =NR, wherein R is a C1 to C10 alkyl group), an amino group (—NH₂, —NH(R′), and —N(R″)(R′″), wherein R′ to R′″ are independently a C1 to C10 alkyl group), an amidino group, a hydrazine or hydrazone group, a carboxyl group, a C1 to C10 alkyl group, a C6 to C20 aryl group, a C3 to C20 cycloalkyl group, a C1 to C10 heteroalkyl group, a C3 to C20 heteroaryl group, and a C2 to C20 heterocycloalkyl group, instead of at least one hydrogen of a functional group, refers to one substituted with at least one substituent selected from =O, =S, =NR (wherein R is a C1 to C10 alkyl group), =PR (wherein R is a C1 to C10 alkyl group), and =SiRR′ (wherein R and R′ are independently a C1 to C10 alkyl group), instead of at least two hydrogens of a functional group, or refers to one substituted with at least one substituent selected from ≡EN, ≡EP, and ≡SiR (wherein R is a C1 to C10 alkyl group), instead of at least three hydrogens of a functional group.

According to one embodiment of the present invention, a rinse solution for a hydrogenated polysiloxazane thin film includes an additive selected from an alcohol-based solvent, an ester-based solvent, a silanol-based solvent, an alkoxysilane-based solvent, an alkylsilazane-based solvent, and a combination thereof.

The alcohol-based solvent includes a C1 to C10 alcohol, for example, a C3 to C10 alcohol, and specifically, n-butanol, octanol, and the like.

The ester-based solvent may be an ester compound represented by RC(=O)OR′ (wherein R and R′ are independently an substituted or unsubstituted C1 to C10 alkyl group or a substituted or unsubstituted C6 to C18 aryl group).

Specific examples of the silanol-based solvent include a trialkylsilanol such as trimethylsilanol, triethylsilanol, and the like. Herein, the alkyl may be a substituted or unsubstituted C1 to C10 alkyl.

Specific examples of the alkoxysilane-based solvent may include a tetraalkoxysilane such as tetraethoxysilane, tetramethoxysilane, and the like. Herein, the alkoxy may be a substituted or unsubstituted C1 to C10 alkoxy.

Specific examples of the alkylsilazane-based solvent may include hexamethyldisilazane, hexaethyldisilazane, and the like. The alkyl may be a substituted or unsubstituted C1 to C10 alkyl.

The additive may suppress reaction of a Si—H group with a Si—N group considered as a polymerization part of hydrogenated polysiloxazane, and thus their solidification or gelation when the hydrogenated polysiloxazane is mixed with the rinse solution.

The additive may be included in an amount of 0.01 wt % to 7 wt % and specifically 0.02 wt % to 5 wt % based on the total weight of the rinse solution for a hydrogenated polysiloxazane thin film. When the additive is included within the range, the additive may be included in an appropriate amount for a reaction with the hydrogenated polysiloxazane and bring about high stabilization effects on solidification or gelation and sufficient stripping characteristics due to excellent dissolubility in the hydrogenated polysiloxazane.

The rinse solution for a hydrogenated polysiloxazane thin film is excellently dissolved in the hydrogenated polysiloxazane. The rinse solution for a hydrogenated polysiloxazane thin film may be prepared by appropriately mixing an aromatic hydrocarbon-based solvent such as xylene, ethylbenzene, propylbenzene, butylbenzene, mesitylene, and the like, an ether-based solvent such as di-n-butylether, anisole, and the like, and a terpine-based solvent such as p-menthane, p-pentane, p-cymene, pinene, turpentine, and the like, and further adding an additive selected from an alcohol-based solvent, an ester-based solvent, a silanol-based solvent, an alkoxysilane-based solvent, an alkylsilazane-based solvent, and a combination thereof, thereto.

The rinse solution may further include a solvent selected from the aromatic hydrocarbon-based solvent, ether-based solvent, terpine-based solvent, and combination thereof in an amount of 93 wt % to 99.9 wt % based on the total weight of the rinse solution.

The rinse solution for a hydrogenated polysiloxazane thin film may be used to pattern a hydrogenated polysiloxazane thin film. The hydrogenated polysiloxazane constituting the hydrogenated polysiloxazane thin film has no particularly-limited properties, but the weight average molecular weight may be in a range of 1,000 to 10,000, and the Si—H₃ group may be in a range of 15 mol % to 35 mol % out of all the Si—H groups in a molecule. The hydrogenated polysiloxazane has an oxygen content ranging from 0.2 wt % to 3 wt %.

The patterned hydrogenated polysiloxazane thin film may be used as an insulation layer for a semiconductor device and the like.

Hereinafter, the present invention is illustrated in more detail with reference to examples, but these examples are not in any sense to be interpreted as limiting the scope of the invention.

### Synthesis Example 1

### Synthesis of Hydrogenated Polysiloxazane

A 2 L reactor equipped with an agitating device and a temperature controller was internally substituted with dry nitrogen. Subsequently, 4.0 g of pure water was injected into 1,500 g of dry pyridine and sufficiently mixed therewith, the resultant was put to the reactor, and the reactor was kept warm at 5° C. The mixture was then agitated while 100 g of dichlorosilane was slowly injected into the reactor over one hour. Then, 70 g of ammonia was slowly added to the reactor over three hours. Dry nitrogen was then injected into the reactor for 30 minutes, and the ammonia remaining in the reactor was removed.

The obtained white slurry product was filtered under a dry nitrogen atmosphere by a 1 μm TEFLON (tetrafluoroethylene) filter, obtaining 1,000 g of a filtered solution. Subsequently, 1,000 g of dry di-n-butylether was added to the filtered solution, a solid concentration of the mixture was adjusted to 20 wt % by substituting a solvent in the mixture from the pyridine to the di-n-butylether three times, and the resultant was filtered through a TEFLON filter having a pore size of 0.03 μm.

The obtained hydrogenated polysiloxazane showed an oxygen content of 1.6 wt %, a polystyrene-reduced weight average molecular weight of 2,100, and a mole ratio between SiH₃/SiH (total) of 0.2.

Herein, the oxygen content was measured using FlashEA 1112 equipment (Thermo Fisher Scientific Inc.), the mole ratio of SiH₃/SiH (total) was measured using a ¹H-NMR analyzer of Avance DPX-300 (Bruker Co.) and CDC1₃ as a lock solvent, and the weight average molecular weight was measured by using GPC: HPLC Pump 1515, RI Detector 2414 (Waters Co.) and Column: KF801, KF802, KF803 (Shodex Inc.).

### Examples 1 to 6 and Comparative Examples 1 to 4

### Rinse Solution for Hydrogenated Polysiloxazane Thin Film

Rinse solutions for a hydrogenated polysiloxazane thin film according to Examples 1 to 6 and Comparative Examples 1 to 4 were prepared to have compositions as in the following Table 1.

TABLE 1

| | Solvent (wt %) | Additive (wt %) |
|---|---|---|
| Example 1 | p-menthane (99.9) | octanol (0.1) |
| Example 2 | p-menthane (99) | octanol (1) |
| Example 3 | p-menthane (95) | octanol (5) |
| Example 4 | di-n-butylether (99.9) | hexamethyldisilazane (0.1) |
| Example 5 | di-n-butylether (99) | hexamethyldisilazane (1) |
| Example 6 | turpentine (99) | tetraethoxysilane (1) - |
| Comparative | di-n-butylether (100) | (0) |
| Example 1 | | |
| Comparative | di-n-butylether (99.995) | hexamethyldisilazane (0.005) |
| Example 2 | | |
| Comparative | di-n-butylether (90) | hexamethyldisilazane (10) |
| Example 3 | | |
| Comparative | di-n-butylether (99) | propylene glycol monomethyl |
| Example 4 | | ether acetate (PGMEA) (1) |

### Evaluation 1: Stability

After putting a magnetic churner in a 500 L glass flask and drying the inside of the flask with nitrogen, 20 cc of each di-n-butylether solution including the hydrogenated polysiloxazane according to Synthesis Example 1 was injected into the flask. Subsequently, 300 cc of the rinse solutions for a hydrogenated polysiloxazane thin film according to Examples 1 to 6 and Comparative Examples 1 to 4 were respectively added to the hydrogenated polysiloxazane, and the mixture was agitated at 200 rpm. The agitated solutions were allowed to stand at 22° C. under relative humidity of 40%, and states of the solutions were examined. Times (gelation days) taken until the solutions in the flask were gelated were regarded as a stability index, and the results are provided in the following Table 2.

### Evaluation 2: Stripping Characteristics

3 cc of a di-n-butylether solution including the hydrogenated polysiloxazane according to Synthesis Example 1 was dripped in the center of a bare silicon water having a diameter of 8 inches set in a spin-coater and spin-coated at 1500 rpm for 20 seconds, and then each rinse solution for a hydrogenated polysiloxazane thin film according to Examples 1 to 6 and Comparative Examples 1 to 4 as shown in Table 1 was sprayed at a flow rate of 10 ml/min for 5 seconds from a height of 3 mm at the external circumference of the wafer. Subsequently, the wafer was heated and dried on a 100° C. hot plate for 3 minutes.

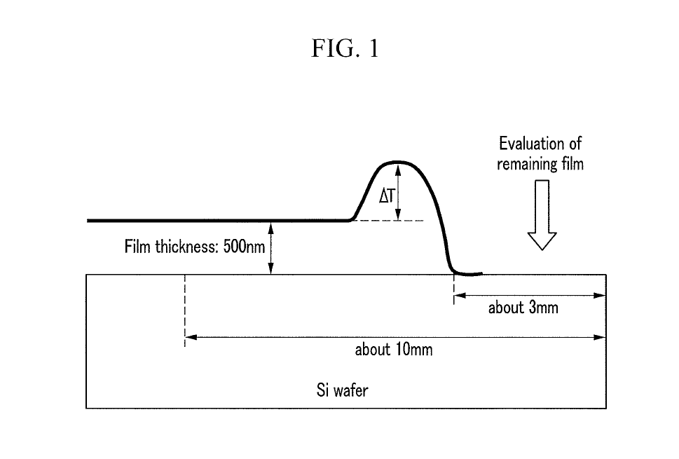

FIG. 1 shows a method of evaluating stripping characteristics of the rinse solutions for a hydrogenated polysiloxazane thin film. FIG. 1 shows the shape of the hydrogenated polysiloxazane thin film after spraying the rinse solution on the hydrogenated polysiloxazane thin film on a silicon wafer. When the end of the hydrogenated polysiloxazane thin film became convex and produced a height change ΔT, 3 mm of the film was removed from the stripping region, that is, from the external wafer circumference, to examine whether the film remained or not. The height change ΔT was measured by scanning the film from the external wafer circumference to about 10 mm by using a spectral reflection film thickness meter ST-4000 (K-MAC) and a SEM S-4800 (Type-2, Hitachi Ltd.) (the SEM was used only around the height change ΔT), and the film residue was examined by using an optical microscope, LV100D (Nikon Inc.) The results are provided in the following Table 2.

TABLE 2

| | Gelation days | ΔT (μm) | Film residue |
|---|---|---|---|
| Example 1 | 9 | 0.3 | No |
| Example 2 | 12 | 0.2 | No |
| Example 3 | 14 | 0.6 | No |
| Example 4 | 10 | 0.4 | No |
| Example 5 | 16 | 0.4 | No |
| Example 6 | 12 | 0.2 | No |
| Comparative Example 1 | 2 (NG) | 0.4 | No |
| Comparative Example 2 | 2 (NG) | 0.4 | No |
| Comparative Example 3 | >20 | 0.4 | Yes (NG) |
| Comparative Example 4 | >3 (NG) | >1 (NG) | Yes (NG) |

As shown in Table 2, the rinse solutions for a hydrogenated polysiloxazane thin film including an additive selected from an alcohol-based solvent, an ester-based solvent, a silanol-based solvent, an alkoxysilane-based solvent, an alkylsilazane-based solvent, and a combination thereof according to Examples 1 to 6 showed excellent results such as a higher number of days until gelation, a low Δ T, and no film residue. On the contrary, the rinse solutions for a hydrogenated polysiloxazane thin film including an additive selected from an alcohol-based solvent, an ester-based solvent, a silanol-based solvent, an alkoxysilane-based solvent, an alkylsilazane-based solvent, and a combination thereof in an insufficient amount out of the reference value or no additive according to Comparative Examples 1 and 2 showed a smaller number of number of days until gelation of less than or equal to 5 days, while the rinse solution including hexamethyldisilazane as an alkylsilazane-based solvent in an excess amount according to Comparative Example 3 showed a film residue and might contaminate equipment or damage device characteristics. On the other hand, the rinse solution using propylene glycol monomethyl ether acetate (PGMEA) as a conventional additive according to Comparative Example 4 showed a small number of days until gelation, a high ΔT, and a film residue, and might contaminate equipment or damage device characteristics.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A rinse solution for a hydrogenated polysiloxazane thin film, the rinse solution comprising an additive selected from an alcohol-based solvent, an ester-based solvent, a silanol-based solvent, an alkoxysilane-based solvent, an alkylsilazane-based solvent, and a combination thereof in an amount of 0.01 wt % to 7 wt % based on the total weight of the rinse solution.

2. The rinse solution of claim 1, wherein the additive is present in an amount of 0.02 wt % to 5 wt % based on the total weight of the rinse solution.

3. The rinse solution of claim 1, wherein the additive is selected from n-butanol, octanol, trimethylsilanol, triethylsilanol, hexamethyldisilazane, hexaethyldisilazane, tetraethoxysilane, tetramethoxysilane, and a combination thereof.

4. The rinse solution of claim 1, which further comprises a solvent selected from an aromatic hydrocarbon-based solvent, an ether-based solvent, a terpine-based solvent, and a combination thereof in an amount of 93 wt % to 99.9 wt % based on the total weight of the rinse solution.

5. The rinse solution of claim 4, wherein the aromatic hydrocarbon-based solvent is selected from xylene, ethylbenzene, propylbenzene, butylbenzene, mesitylene, and a combination thereof.

6. The rinse solution of claim 4, wherein the ether-based solvent is selected from di-n-butylether, anisole, and a combination thereof.

7. The rinse solution of claim 4, wherein the terpine-based solvent is selected from p-menthane, p-pentane, p-cymene, pinene, turpentine, and a combination thereof.

8. A method of patterning a hydrogenated polysiloxazane thin film by using the rinse solution of claim 1.

9. An insulation layer formed by using the rinse solution of claim 1.
